(19) United States
(12) Patent Application Publication
(10) Pub. No.: US 2023/0011561 A1
(43) Pub. Date: Jan. 12, 2023

(54) PIEZOELECTRIC MICROPHONE WITH ENHANCED ANCHOR

(71) Applicant: SKYWORKS SOLUTIONS, INC., Irvine, CA (US)

(72) Inventors: You Qian, Singapore (SG); Humberto Campanella-Pineda, Singapore (SG); Guofeng Chen, Fremont, CA (US); Rakesh Kumar, Singapore (SG)

(21) Appl. No.: 17/810,870

(22) Filed: Jul. 6, 2022

Related U.S. Application Data
(60) Provisional application No. 63/220,034, filed on Jul. 9, 2021.

(51) Int. Cl. B81B 3/00; H04R 17/02; B81C 1/00

(52) U.S. Cl. CPC B81B 3/0086; H04R 17/02; B81C 1/00166; H04R 2201/003; B81B 2203/0315; B81B 2201/0257; B81B 2203/0118; B81B 2203/04; B81B 2203/0307; B81C 2201/0132

(57) ABSTRACT

A piezoelectric microelectromechanical systems (MEMS) microphone is provided comprising a substrate including walls defining a cavity and at least one of the walls defining an anchor region, a piezoelectric film layer supported by the substrate at the anchor region; an electrode disposed over the piezoelectric film layer and adjacent the anchor region and including an edge adjacent the anchor region having two straight portions and a protruding portion between the two straight portions, and the wall of the cavity that defines the anchor region including an indent corresponding in shape to the protruding portion of the electrode. A method of manufacturing such a MEMS microphone is also provided.

### CROSS-REFERENCE TO RELATED APPLICATIONS

This application claims priority under 35 U.S.C. § 119(e) to U.S. Provisional Patent Application Ser. No. 63/220,034, titled “PIEZOELECTRIC MICROPHONE WITH ENHANCED ANCHOR,” filed Jul. 9, 2021, the entire contents of which is incorporated by reference herein for all purposes.

### BACKGROUND

### Field

The present disclosure relates to a piezoelectric microelectromechanical systems (MEMS) microphone, and in particular a piezoelectric MEMS microphone with improved electrode.

### Description of the Related Technology

A MEMS microphone is a micro-machined electromechanical device used to convert sound pressure (e.g., voice sound) to an electrical signal (e.g., voltage). MEMS microphones are widely used in mobile devices, headsets, smart speakers and other voice-interface devices or systems. Conventional capacitive MEMS microphones suffer from high power consumption (e.g., large bias voltage) and reliability, for example when used in a harsh environment (e.g., when exposed to dust and/or water).

Piezoelectric MEMS microphones have been used to address the deficiencies of capacitive MEMS microphones. Piezoelectric MEMS microphones offer a constant listening capability while consuming almost no power (e.g., no bias voltage is needed), are robust and immune to water and dust contamination.

Piezoelectric MEMS microphones work on the principle of piezoelectric effect, so that they convert acoustic signals to electric signal when sound waves vibrate the piezoelectric sensor. The sound waves bend the piezoelectric film layers of a cantilevered beam or non-cantilevered beam, causing stress and strain, resulting in charges being generated in the piezoelectric film layers. The charges are converted to voltage as an output signal, by the placement of one or more electrodes on the piezoelectric film layers.

### SUMMARY

According to one aspect there is provided a piezoelectric microelectromechanical systems microphone. The piezoelectric microelectromechanical systems microphone comprises a substrate having walls defining a cavity, at least one of the walls defining an anchor region, a piezoelectric film layer supported by the substrate at the anchor region, an electrode disposed over the piezoelectric film layer and adjacent the anchor region and having an edge adjacent the anchor region including two straight portions and a protruding portion between the two straight portions, and the wall of the cavity that defines the anchor region having an indent corresponding in shape to the protruding portion of the electrode.

In one example the protruding portion of the electrode defines a curve. This shape is advantageous as the high stress and strain region of the piezoelectric material may be circular in shape.

In one example the protruding portion of the electrode defines a polygon. This shape is advantageous as the protruding portion may be designed to match the shape of the area of highest stress and strain.

In one example the protruding portion is in the middle of the edge of the electrode. This has the advantage that the highest stress and strain of the cantilevered beam is at the middle of the beam adjacent the anchor region. Therefore a larger area of electrode at this location provides a larger voltage output.

In one example the piezoelectric film layer and electrode define a beam, wherein the beam is cantilevered such that it has a free end and a fixed end.

In one example the microphone further comprises a second piezoelectric layer. This has the advantage that the piezoelectric layers may have different average stresses, such that they may be chosen to compensate for intrinsic stress gradients formed during manufacture.

In one example the piezoelectric film layer has a triangular shape.

In one example the electrode is a truncated triangle with a protruding portion, such that the free end of the piezoelectric film layer is exposed. This is advantageous as it is optimal to reduce the size of the electrode where there is the least stress and strain, as it is optimal to lower the area of the electrode, and thus the capacitance, so that the device has the highest output voltage possible. Therefore, it is advantageous to remove a portion of the electrode at the free end, where there is the least stress and strain.

In one example the protruding portion has a width of 300 micrometers and a depth of 5 micrometers. A protruding portion with a larger width would result in a larger deflection of the cantilevered beam, resulting in a lower acoustic resistance, and thus lower sensitivity.

In one example the microphone further comprises at least one additional electrode. This has the advantage that one additional electrode results in the energy being created by both the tensile and compressive stresses being converted to voltage. For example, if the piezoelectric film layer bends out of the cavity, the cavity side surface of the piezoelectric film layer will have tensile stress and create energy due to the piezoelectric effect. The surface of the piezoelectric film layer on the side away from the cavity will have compressive stress, and create energy due to the piezoelectric effect. In the example in which there are two additional electrodes, there may be an additional electrode located in between two piezoelectric film layers, such that this third electrode may act as a ground electrode.

According to another aspect there is provided a method of making a piezoelectric microelectromechanical systems microphone. The method comprises depositing one or more electrodes each including an edge adjacent an anchor region having two straight portions and a protruding portion between the two straight portions, and etching a cavity including one or more walls each having an indent corresponding in shape to the protruding portion of the electrode.

In one example the method of etching the cavity further comprises etching a trench in a silicon substrate from a front side, filling the trench with a silicon dioxide and oxidizing a surface of a substrate to form an oxidation layer, applying a piezoelectric film layer over the oxidation layer, etching a gap in the piezoelectric film layer from the front side, etching the silicon substrate from the back side, and etching the silicon dioxide from the back side.

In one example the method further comprises etching a second trench wherein the first and second trenches define the edges of the cavity. This has the advantage that the cavity edges are defined by front etching, and are therefore more accurately etched from the backside, as the silicon cannot be etched wider than the trenches, up to the depth at which the trenches are made perpendicular into the silicon.

In one example trenches each comprise two straight edges and an indent to correspond to the protrusion of the electrode. This has the advantage that the cavity wall edge will be aligned with the electrode edge, such that there is no overlap, or the overlap is minimal. The piezoelectric film layer only has stress and strain where it moves, and therefore it is advantageous to not have electrode covering the anchor region, instead this method ensures the electrode is only covering the stressed and strained portion of piezoelectric film layer.

In one example the indent has a width of 300 micrometers and a depth of 5 micrometers.

In one example the method further comprises etching two or more additional trenches, defining pillars. In one example, the method further comprises oxidizing the pillars. In one example the etching of the silicon dioxide comprises etching the pillars to form a cavity. This has the advantage that only silicon dioxide etching is required to accurately etch the cavity from the back side of the substrate.

According to another aspect there is provided a wireless mobile device. The wireless mobile device comprises one or more antennas, a front end system that communicates with the one or more antennas; and one or more piezoelectric microelectromechanical systems microphones, each microphone including: a substrate having walls defining a cavity and at least one of the walls defining an anchor region a piezoelectric film layer supported by the substrate at the anchor region such that the piezoelectric film layer is cantilevered, the piezoelectric film layer being formed to introduce differential stress between a front surface of the piezoelectric film layer oriented away from the cavity and a back surface of the piezoelectric film layer oriented towards the cavity such that the piezoelectric film layer is bent into the cavity, and an electrode disposed over the piezoelectric film layer and adjacent the anchor region.

In one example the protruding portion of the wireless device of the electrode defines a curve.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1A is a cross-sectional view of a known MEMS microphone;

FIG. 1B is a plan view of a known MEMS microphone;

FIG. 1C is a cross-sectional view of a known MEMS microphone arrangement;

FIG. 1D is a cross-section view of a known MEMS microphone arrangement;

FIG. 2A is a plan view of a known cantilevered beam;

FIG. 2B is a plan view of known MEMS microphone including the cantilevered beam and electrodes of FIG. 2A;

FIG. 2C is a cross-sectional view of the MEMS microphone of FIG. 2B;

FIG. 3 is a plan view of a comparison of two electrodes according to aspects disclosed herein;

FIG. 4 is a plan view of a beam including an electrode, piezoelectric film layer and anchor region according to aspects disclosed herein;

FIG. 5A is a plan view of a piezoelectric MEMS microphone according to aspects disclosed herein;

FIG. 5B is a plan view of a cavity according to aspects disclosed herein;

FIG. 6A is a cross-sectional view of a piezoelectric MEMS microphone according to aspects disclosed herein;

FIG. 6B is a cross-sectional view of a piezoelectric MEMS microphone according to aspects disclosed herein;

FIG. 7A-7D are a cross-sectional view of steps of manufacturing a piezoelectric MEMS microphone in accordance with aspects disclosed herein;

FIG. 8A-8F are a cross-sectional view of steps of manufacturing a piezoelectric MEMS microphone in accordance with aspects disclosed herein;

FIG. 9A-9E are a cross-sectional view of steps of manufacturing a piezoelectric MEMS microphone in accordance with aspects disclosed herein; and

FIG. 10 is a schematic diagram of a wireless device in accordance with aspects disclosed herein.

### DETAILED DESCRIPTION

Aspects and embodiments described herein are directed to a piezoelectric MEMS microphone comprising an electrode having a protrusion, and a wall of a cavity having a corresponding indent, the method of manufacturing the microphone, and a wireless mobile device involving the microphone for improving the sensitivity of the microphone. The protrusion and corresponding indent allows for an electrode to be disposed over the piezoelectric film layers with the highest stress and strain, thus increasing the output voltage, and therefore the sensitivity of the microphone.

Methods of designing a piezoelectric MEMS microphones are aimed at maximizing the output voltage, by designing electrodes of differing shapes and placements. If maximum energy is required, the system may be designed such that the electrode does not fully cover the whole cantilevered beam, such that the area is smaller, and thus the capacitance is smaller, resulting in a higher voltage output. However, we have appreciated in the present application, that the output voltage may be further optimized using different designs and techniques, as described herein.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

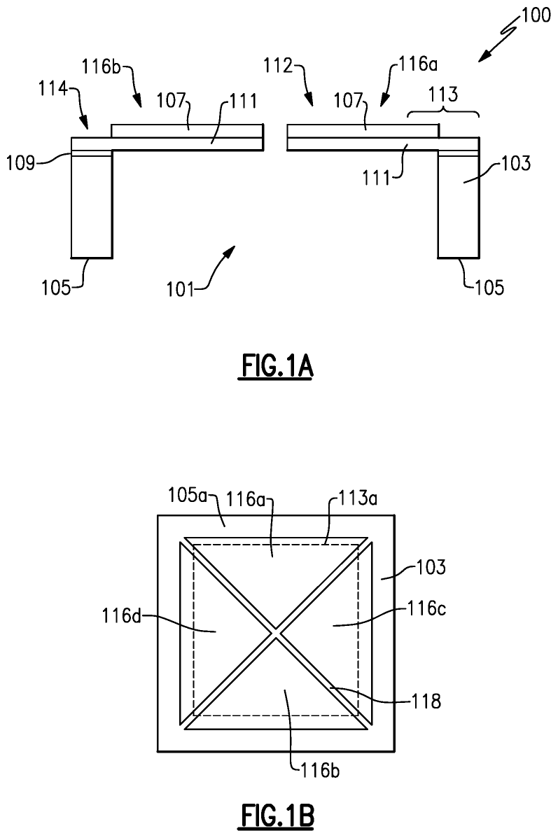

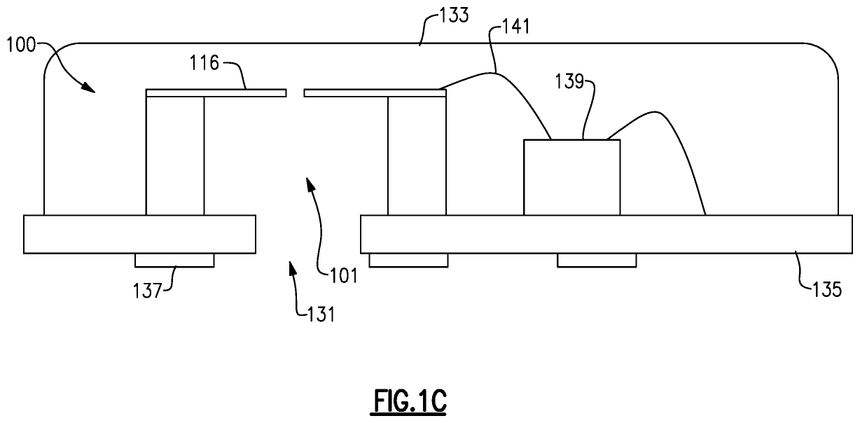

FIG. 1A shows a cross-sectional view of a known implementation of a piezoelectric microelectromechanical systems (MEMS) microphone 100 (hereinafter the “microphone”). The microphone 100 is a piezoelectric MEMS cantilever microphone. The microphone 100 comprises a substrate 103. The substrate 103 is optionally made of silicon. The substrate 103 has two side walls 105, arranged such that they extend perpendicular to the length of the one or more cantilevered beams 116. The cantilevered beams 116a and 116b are composed of one or more piezoelectric film layers 111. Two further end walls (not shown) complete the cavity on opposite sides, such that they meet the side walls at right angles, and a further structure, described in relation to FIG. 1C later, may be on the underside of the cavity. The cavity is preferably 400 micrometers deep. The walls are preferably around 100-500 micrometers thick. At least one of the side walls 105 defines an anchor region 113. The anchor region is preferably around 100-500 micrometers thick. The anchor region is the area where the piezoelectric film layer 111 is coupled to and supported by one of the side walls. The microphone 100 optionally comprises an insulation layer 109 disposed on a surface of the substrate 103. The insulation layer is optionally silicon dioxide. The piezoelectric film layer 111 is supported by the substrate 103 at the anchor region 113, such that the piezoelectric film layer 111 is cantilevered and extends between a fixed end 114 and a free end 112. Although the microphone is illustrated with two cantilevered beams, extending from opposite walls, such that the free end of one cantilevered beam 116a is separated from the free end of the second cantilevered beam 116b by a gap centered over the cavity 101, it will be noted that there may only be one cantilevered beam, such that it extends across the cavity, and is separated from the second cavity wall by a gap. The size of the gap between the free ends of the one or more beams is preferably minimized, such that air flow into and out of the cavity is minimized, thus increasing sensitivity of the device. The gap between the free ends is preferably 100 nanometers-1 micrometer. It will be appreciated that FIG. 1A is a cross-sectional view, such that there may be two additional cantilevered beams, one extending over the cavity from a first end wall and the other extending over the cavity from a second end wall. In the arrangement comprising four cantilevered beams, the beams are triangular in shape, as shown in FIG. 1B. Although the beams are illustrated as extending across the cavity, such that they are perpendicular to the surface of the substrate, i.e., are flat, it will be noted that the beam may bend into, or out of the cavity.

In the embodiments described herein, at least one electrode 107 is arranged over the piezoelectric film layer, such that the at least one electrode may be disposed over the piezoelectric film layer, such the at least one electrode is located on the cavity side of the piezoelectric film layer, or such that the at least one electrode is located on the other side of the piezoelectric film layer away from the cavity. In some embodiments the arrangement may comprise two or three electrodes. In some embodiments there may be two piezoelectric film layers, such that an electrode may be positioned between the two piezoelectric film layers. FIG. 1D illustrates a preferred embodiment in which there are three electrodes 107a, 107b and 107c. The electrodes are arranged such that electrode 107a is arranged on the piezoelectric film layer 111a, and electrode 107b is arranged on the piezoelectric film layer 111b, and electrode 107c is arranged between the two piezoelectric film layers 111a and 111b. Together the piezoelectric film layer(s) and electrode(s) form a cantilevered beam 116. It will be appreciated that there are two cantilevered beams 116a and 116b shown in the cross-sectional view of FIG. 1D, however as illustrated in FIG. 1B, the three dimensional microphone arrangement may comprise four cantilevered beams 116a-116d. The electrode is optionally positioned adjacent the anchor region 113. The insulation layer 109 provides insulation between an electrode, disposed on the cavity side of the piezoelectric film layer, and the silicon substrate 103.

The microphone may comprise two piezoelectric film layers where one is deposited on the other, herein referred to as a stress compensation technique. The manufacture of the piezoelectric film layers by deposition results in a stress gradient along the piezoelectric film layer, causing it to bend. Therefore, by manufacturing a cantilevered beam comprising two piezoelectric film layers the layers may be manufactured such that they have different average stress. Therefore, their combination results in a cantilevered beam with a reduced stress gradient, resulting in a flatter cantilevered beam, and thus a more sensitive microphone.

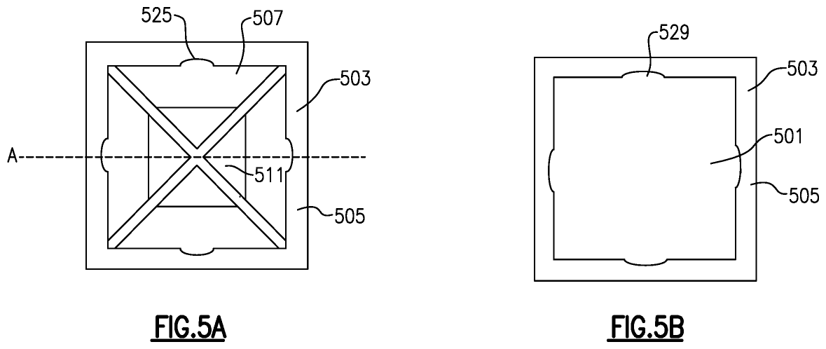

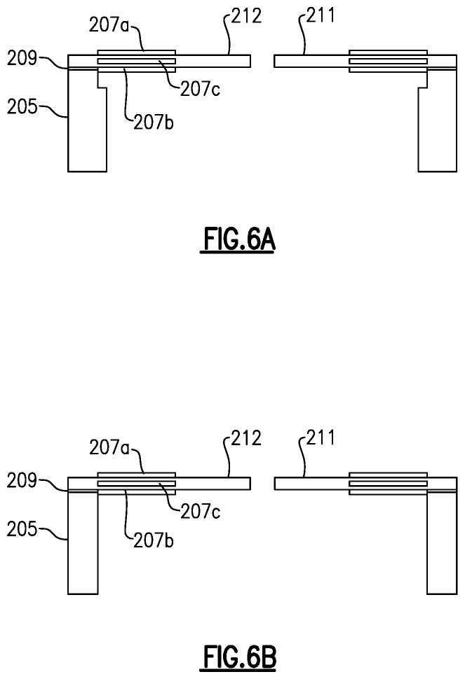

The electrode may be disposed over the entirety of the piezoelectric layer, such that in the example in which there are three electrodes and two piezoelectric layers, each of the piezoelectric film layers are sandwiched between two of the three electrodes, as illustrated in FIGS. 6A-6B. In the arrangement of FIGS. 1A and 1B, the electrode is the same size and shape as the piezoelectric layer, up until the anchor region, defined by the dashed line of FIG. 1B, such that the edge of the electrode is in line with the edge of the cavity wall, i.e., the electrode does not overlap with the cavity walls. This arrangement results in all of the charge created by the stress and strain of the piezoelectric film layer, due to the bending of the beam as a result of sound, being output. However, the maximum energy output is relative to C*V², where C is capacitance, and V is voltage, such that a smaller capacitance will result in a larger output voltage for the same maximum energy. Therefore, we have appreciated that a smaller area of electrode is preferable, to result in a smaller capacitance, and thus to achieve higher energy output.

FIG. 1B shows a plan view of the known arrangement of FIG. 1A. The beams 116a-116d are illustrated, such that they are each anchored to the cavity walls 105, at anchor regions 113. This has been illustrated for beam 116a, anchored to cavity wall 105a at anchor region 113a. It will be appreciated that this arrangement is repeated for each of 116b-116d. The dashed line in FIG. 1B illustrates the overlap of the beam 116a-116d with the cavity walls 105, such that beam illustrated on the outer side of the dashed line is supported by the anchor region, and has a cavity wall on its back side.

As shown, on the inside of the dashed line, the beam is located above the cavity 101, such that the gap 118 between the beams leads to the cavity 101. The gap allows air flow into and out of the cavity around the periphery of each of the beams.

FIG. 1C illustrates a cross-sectional view of a microphone arrangement. It will be appreciated that this is an example embodiment for illustrative purposes, and the microphone can be included in a variety of different arrangements. As illustrated, the microphone 100 of FIG. 1C is located within a cap 133. The cap may be flexible or rigid, and may be any suitable material such as a metallic material. The cap creates a seal with a substrate 135 (for example a printed circuit board), such that air only flows into and out of the arrangement via a sound inlet 131. The substrate 135 may be any suitable material. The cap 133 also mitigates electromagnetic interference. Sound waves enter the arrangement, causing the cantilevered beam 116 to bend and produce voltage due to the piezoelectric effect, as described herein. The arrangement comprises at least one solder pad 137 such that the microphone arrangement may be soldered to external devices, not shown here. The microphone arrangement further comprises an application specific integrated circuit chip/die (“ASIC”) 139. The MEMS microphone is electrically connected by wire bonding 141. Although not shown, it will be appreciated that the wire bonding may be connected to the one or more electrodes of the microphone, as described herein.

It will be noted that FIG. 1C is a cross-sectional view of the microphone arrangement, such that the one or more solder pads, substrate 135, MEMS microphone 100, ASIC 139, and cap 133 extend into the page such that they are three-dimensional, as described in relation to other embodiments disclosed herein.

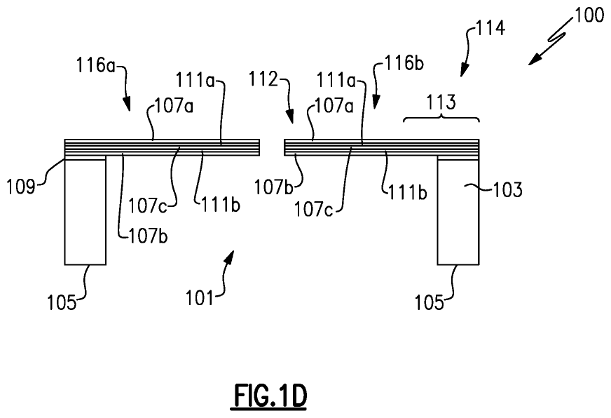

FIG. 2A illustrates a plan view of an example known cantilevered beam 216, comprising a piezoelectric film layer 211 and electrode 207. It will be noted that although the example illustrates a triangular beam 216, the beam 216 may be any shape, and the electrode 207 and piezoelectric film layer 211 will be shaped accordingly. The dashed line illustrates the edge of the electrode 207. The figure illustrates an electrode 207 deposited over a piezoelectric film layer 211. The electrode 207 is a truncated triangle, with the base of the triangle being the same shape as the base of the piezoelectric film layer 211, such that the piezoelectric film layer is exposed at the tip of the triangle, but not at the base of the triangle.

FIG. 2B shows a plan view of a known example of an electrode, as described in relation to FIG. 2A, in relation to the additional features of the microphone device. The features are the same as those described in relation to FIG. 1B. It will be noted that the plan view is looking from the front side of the device, such that optional additional electrodes are not illustrated.

FIG. 2C illustrates a cross-sectional view of the arrangement of FIGS. 2A-B. It will be noted that the features described in relation to FIGS. 1A and 1B are the same in the arrangement of FIGS. 2A-C. As shown, the base of the triangle is located adjacent the anchor region, such that the edge of the base of the electrode is at least in line with the side of the cavity wall. The arrangement shown results in a smaller area of electrode, and thus a smaller capacitance. It will be noted that the shortened electrode may be located at the free end of the piezoelectric film layer, however the region of the piezoelectric film layer adjacent the anchor region experiences the most stress and strain, and therefore produces the most energy per unit area. Therefore, the placement of the truncated electrode adjacent to the anchor region results in a higher output voltage. It will be noted that although not shown, there may be a second electrode, located on the cavity side of the piezoelectric film layer as well as the opposite side of the piezoelectric film layer. In this arrangement, the electrodes would be equal shape and size and deposited such that they are in line with each other.

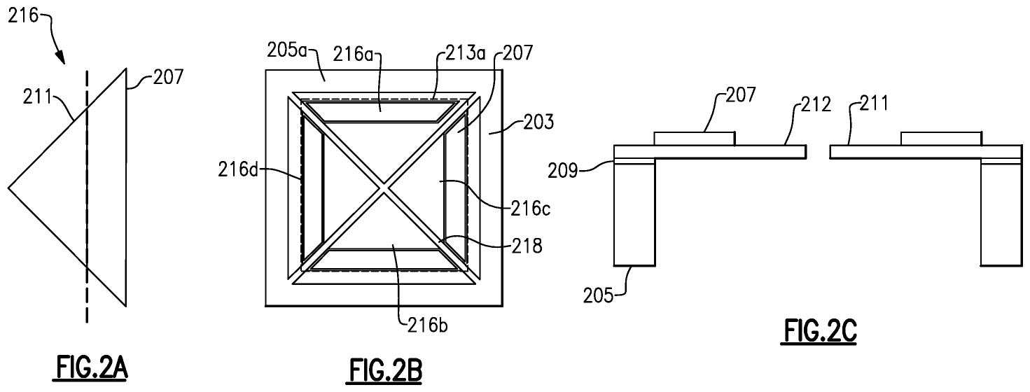

FIGS. 3, 4, 5A-5B and 6A-6B illustrate a preferred embodiment. FIG. 3 illustrates a plan view of an electrode which is used in the preferred embodiment. The microphone of the preferred embodiment may be part of an arrangement as described in relation to FIG. 1C. It will be noted that for illustrative purposes the electrode of the embodiment of FIGS. 2A-C is shown as a dashed outline, as a truncated triangle shape. It will be noted that any suitable conductive material can be used for the one or more electrodes, for example molybdenum or titanium. The solid outline illustrates the preferred embodiment. As shown, the electrode comprises three straight edges 325a, 325b, 325c, and a fourth edge 325d comprising a protruding portion 327. As shown, the edge adjacent the anchor portion, 325d, includes two straight portions and a protruding portion 327 between the two straight portions. It will be noted that although the electrode is shown as a truncated triangular shape with a protruding portion 327, the electrode and piezoelectric film layer may be a variety of shapes involving the protrusion. For example, the piezoelectric film layer may be rectangular and therefore the electrode may also be rectangular in shape, with a protruding portion. It will be appreciated that any shaped piezoelectric film layer and its corresponding electrode involving the protrusion may be used, however the edge adjacent the anchor region of the electrode other than the protruding portion 327 is preferably straight. The protruding portion may be a semicircle or a semi ellipse in cross-section from the plan view, and may be located in the center of the edge of the electrode adjacent the anchor region, i.e., the portion is protruding from the base portion. The width of the semicircle or semi ellipse may be substantially less than the length of the edge of the electrode. It has been appreciated that a larger width of the protrusion may result in a larger deflection of the beam, and therefore the protrusion has been optimized such that the area of the electrode in the high strain region is increased, without causing unsatisfactory deflection of the cantilever. It is noted that the preferred arrangement is a cantilevered beam, but the techniques herein of a protruding portion of the electrode and corresponding indent in the cavity may be applied to non-cantilevered MEMS arrangements. It will be appreciated that the protruding portion may be any other shape such that the surface area of the edge of the electrode 325d adjacent to the anchor region is greater than that of the region adjacent the anchor region of the truncated triangle of FIG. 2. The protrusion increases the area of the electrode covering the high stress and strain area of the piezoelectric film layer. Preferably the one or more piezoelectric film layers are formed from Aluminum Nitride, however it will be appreciated that any suitable piezoelectric material may be used, such as PZT, ZnO, PVDF, PMN-PT, scandium-doped aluminum nitride or others. The stress and strain is highest at the area adjacent the anchor, and therefore the protrusion 327 of the preferred embodiment increases the surface area at the highest stress and strain region. In the preferred embodiment an equal area to that added by the protrusion is removed from the edge of the electrode closest to the free end of the beam, 325b, such that the overall area of the electrode is the same. This area is lowest in stress and strain, and therefore, its removal decreases capacitance while not substantially decreasing the voltage output, as the removed area produces the least charge. Therefore, the preferred embodiment results in an increased sensitivity, due to more area in the high stress and strain region, without increasing the capacitance, resulting in a higher output voltage.

FIG. 4 illustrates a plan of the embodiment of FIG. 3. The dashed outline illustrates the piezoelectric film layer 411. Thus the shape of the cantilevered beam 416 is the portion of the piezoelectric film layer which extends over the cavity, and is not overlapping with the cavity wall 405. It will be noted that the features may have any dimensions; in the preferred embodiment, the beam 416 is around 370 micrometers long from the edge of the cavity wall, i.e., from the anchor region. The beam length is labelled a in FIG. 4. It will be noted that, as illustrated in FIG. 4, as well as FIGS. 2C and 1A, the piezoelectric film layer will overlap the cavity wall 405, at the anchor region, such that the length of the piezoelectric film layer will be longer than the length of the beam 416. In the preferred embodiment the base portion of the beam has a width, labelled b, of around 740 micrometers, and the beam is around 0.6 micrometers thick. The piezoelectric film layer is preferably 0.4-1 nanometers, and the electrode is preferably 5-100 nanometers. The thickness is not shown in FIG. 4, however it will be appreciated that the thickness is the distance between the surface of the beam on the cavity side and the surface of the beam on the surface on the opposite side to the cavity. We have appreciated that the performance of the microphone can be optimized by optimizing the depth and the width of the electrode 407. We have calculated that the optimal dimensions of the electrode protrusion 427 has around a 300 micrometer width, labeled c in FIG. 4, and a depth of 5 micrometers, labelled d in FIG. 4. The depth of the protrusion 427 is the furthest distance which the protrusion 427 protrudes from the straight edge of the electrode 425d.

We have calculated that the microphone using the electrode of the preferred embodiment increases the sensitivity of the microphone by around 0.15 dB, which is the optimized sensitivity.

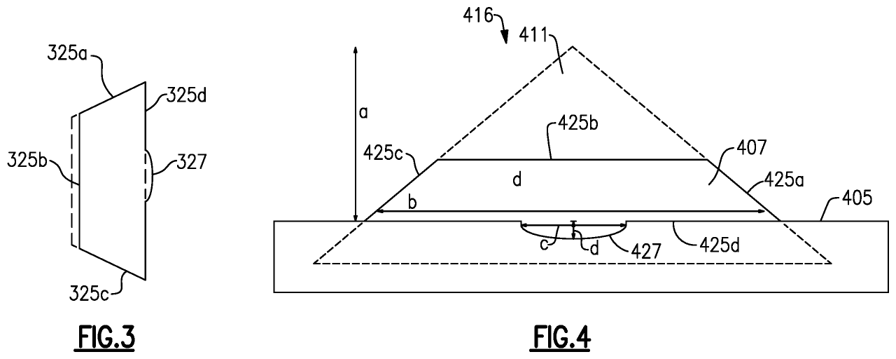

FIGS. 5A and 5B illustrate a plan view of the preferred embodiment of FIGS. 3 and 4. The electrodes 507 are illustrated over the piezoelectric film layer 511, such that they are on the opposite side of the beam to the cavity 501. However, it will be appreciated at least one more additional electrode is located on the cavity side of each piezoelectric film layer.

FIG. 5A shows a plan view of the device illustrating the substrate 503, cavity walls 505, piezoelectric material 511, and electrode 507. As described in relation to FIGS. 2A-2C, 3 and 4, the electrode is a truncated triangular shape, such that the piezoelectric film layer is exposed at its free end, but is not exposed at its base region. There is a protruding portion of electrode 525 such that the portion of the electrode adjacent the anchor region does not have a straight edge. For illustrative purposes the overlap of the piezoelectric film layer 511 with the cavity wall is not shown. However, it will be noted that the piezoelectric film layer will extend past the edge of the base portion of the electrode, such that it is supported by the anchor region of the cavity walls, as shown in FIGS. 2 and 4. It will be noted that, as described in relation to FIGS. 1A and 2C, there may be an insulating layer located between the piezoelectric film layer and the substrate 503. The substrate 503 may be silicon, in which case the insulating layer is silicon dioxide. However, it will be appreciated that any suitable substrate material, and insulating material may be used.

FIG. 5B shows a plan view of the cavity walls formed from the substrate in the preferred embodiment. For illustrative purposes, there are no additional features included in the figure, such that it solely illustrates the shape of the cavity wall 505. We have appreciated that in the preferred embodiment of the electrode, the cavity walls are preferably indented, such that the protruding portion of the electrode 525 on the cavity side of the beam fits into the indent 529. In the preferred embodiment, the cavity wall has indents 529 of the exact shape and size of the electrode protrusion 525, such that the edge at the base portion of the electrode on the cavity side of the beam is in contact with the cavity wall along its entire edge. The electrode protrusion and the cavity wall indent are advantageously equal in shape and size. The addition of a protrusion at the anchor region of the electrode, and a corresponding indent in the cavity wall results in the cantilevered beam being free to bend at the protrusion and thus have stress and strain, and result in output voltage. Without an indent in the cavity wall, there would be no voltage for the electrode to collect at its protrusion. In the preferred embodiment a higher area of the piezoelectric film layer is under high stress and strain than a device with a straight anchor region. This results in a higher sensitivity of the microphone. The electrode edge is at least in line with the cavity wall. However, it will be appreciated that due to manufacturing tolerances, which may be around 2-5 micrometers, the electrode may be designed to overlap the cavity walls to account for possible manufacturing tolerances.

It will be appreciated that an electrode on the opposite side to the cavity does not come in contact with the cavity wall edge, as the electrode is over the piezoelectric film layer, which itself is supported by the cavity wall. However, both of the electrodes will be the same shape and size and aligned such that they may perform their purpose of collecting charge.

Preferably the preferred embodiment of FIGS. 3, 4, 5A-5B and 6A-6B comprise two piezoelectric film layers, and three electrodes, as described in relation to FIG. 1D and FIGS. 6A and 6B. In this embodiment the electrodes 207a, 207b, 207c are located on the cavity side of the cantilevered beam 207b, on the opposite side to the cavity 207a, and in between the two piezoelectric film layers 207c. It will be appreciated that in an embodiment in which there are only two electrodes, the two electrodes may be located on opposite sides of the cantilevered beam, such that the one or more piezoelectric layers are sandwiched between the two electrodes. However, it will be appreciated that an embodiment with two electrodes may have one electrode located in the center of the two piezoelectric film layers, and one on the cavity side of the cantilevered beam, or it may have one electrode located in the center of the piezoelectric film layers and one on the opposite side of the cantilevered beam to the cavity.

FIGS. 6A and 6B show a cross-sectional view of the preferred embodiment, along the line labelled A in FIG. 5A, as described in relation to FIGS. 3-5. The preferred embodiment comprises three electrodes, 207a, 207b and 207c, and two piezoelectric film layers, wherein the center electrode is disposed between the first and second piezoelectric film layers. The two piezoelectric film layers are illustrated here as one beam 211, for illustrative purposes, wherein the beam 211 is cantilevered such that it has a free end. As described in FIG. 2, there is an insulating layer located between the walls of the cavity 205 and the piezoelectric film layer 211. It will be appreciated that the insulating layer may be indented to correspond to the indent 529 in the cavity wall, as described in relation to FIG. 5. It has been illustrated in FIGS. 6A and 6B that the cavity wall and insulating layer 209 are indented to correspond to the protrusion of the electrode, such that along the line labelled A in FIG. 5A, the cross-section shows an indented cavity wall and insulating layer. It is shown in FIG. 6A that the cavity wall may be indented to correspond to the protrusion of the electrode, where the indent extends towards the back side of the cavity to a depth deep enough to allow the cantilevered beam to bend sufficiently. It is shown in FIG. 6B that the indent may extend the entire length of the wall 205, such that the wall is the same shape in the cross-sectional view along its entire length, as is shown in FIG. 6B wherein the cavity wall is straight. In the preferred embodiment, the cavity may be around 400 micrometers in depth, such that the cavity walls may be around 400 micrometers in depth.

### Manufacturing of a Piezoelectric MEMS Microphone

The method of manufacturing of the piezoelectric MEMS microphone will now be described. It is noted that although this technique is described in relation to the microphone described in this application, it is compatible with any piezoelectric MEMS microphone. It will be appreciated that the features of the microphone as described in the above description may be implemented here, such as but not limited to the materials and dimensions.

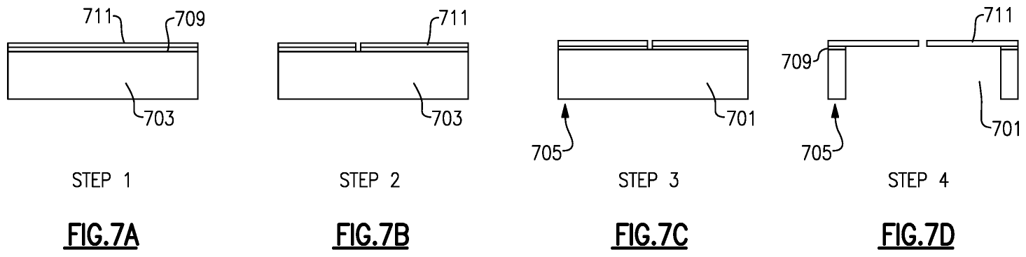

FIGS. 7A-7D illustrates a cross-sectional view of a first method for manufacturing the piezoelectric MEMS device as described in embodiments disclosed herein. The cross-sectional view is taken along the line A as illustrated in FIG. 5A. It will be appreciated that in the arrangement, the cavity comprises four walls, two end walls and two side walls, such that they meet at right angles to form a rectangular or square cross-section. The arrangement also comprises four cantilevered beams, such that that each beam has a fixed end supported by the anchor region of the device, i.e., supported by the cavity walls. Therefore, it is noted that the methods described herein, such as etching, will be applied to the additional two cavity walls and additional two beams. It will be noted that any shape of cavity may be used, such that the four walls do not meet at right angles, or such that there may only be three walls. It will be noted that any shape of beam may be used, such that the beams extend to form a rectangle in the plane parallel to the surface of the substrate, or such that there is only one beam.

The first step of FIG. 7A illustrates a piezoelectric film layer 711 disposed on a substrate 703. Preferably the piezoelectric film layer 711 is composed of Aluminum Nitride, however it will be appreciated that any suitable piezoelectric material may be used, such as scandium-doped aluminum nitride. Preferably the substrate 703 is composed of Silicon, however it will be appreciated that any suitable material may be used. Preferably there is an insulating layer 709 located between the piezoelectric film layer 711 and substrate 705. Preferably the insulating layer is silicon dioxide, and is formed by oxidizing the silicon substrate, optionally by thermal oxidation, such that a layer of silicon dioxide forms on the surface. Although not shown, the electrodes are located on both the back side and front side of the piezoelectric material, and in some arrangements a third may be located between piezoelectric film layers. The least one piezoelectric film layer, and the at least one electrode may be formed by a physical vapor deposition. As illustrated the piezoelectric film layer 711 and substrate 703 are solid in the first step of manufacture.

Step 2, illustrated in FIG. 7B, illustrates the etching of the piezoelectric layer 711. The etch is created from the front side using a dry anisotropic etching process to create a slit in the one or more piezoelectric film layers which is substantially perpendicular to the surface of the substrate, enabling the cantilever to move freely in a direction perpendicular to the surface of the substrate 703. Preferably the slit is etched such that the gap between the cantilevers is around 100 nanometers-1 micrometer. It will be noted that any suitable etching process may be used. In the arrangements described herein, the slit is etched in the center of the one or more piezoelectric film layers.

To create a cavity 701, step 3, illustrated in 7C, comprises etching an area from the back side of the substrate 703. The etching may be isotropic or anisotropic silicon etching, such that the silicon is etched, but the silicon dioxide is not etched, and therefore acts as a protection layer for the piezoelectric material 711, and the electrodes. As described in relation to the embodiment of FIG. 4, the electrode preferably has a protrusion with a 300 micrometer width and a depth of 5 micrometers. Therefore, the cavity wall is manufactured to have an indent of width 300 micrometers and a depth of 5 micrometers. The cavity wall and electrodes may be manufactured such that there is a small overlap, to take into account manufacturing tolerances, which may be around 2-5 micrometers.

Step 4, illustrated in FIG. 7D, comprises etching the silicon dioxide by a silicon dioxide etch. The etching process may be isotropic or anisotropic. This etching step removes the remaining silicon dioxide from the underside of the beam, but the insulating layer located between the cavity walls and the piezoelectric layer is protected by the silicon walls and remains. This etching process creates the walls of the cavity 705 from the substrate 703. It will be noted that the FIGS. 7A-7D are cross-sectional views, and thus the indent in the cavity wall is not shown. However, during the etching from the back side of the cavity, the etching may be controlled so as to form a cavity with a similar wall edge to the edge of the protrusion of the electrode.

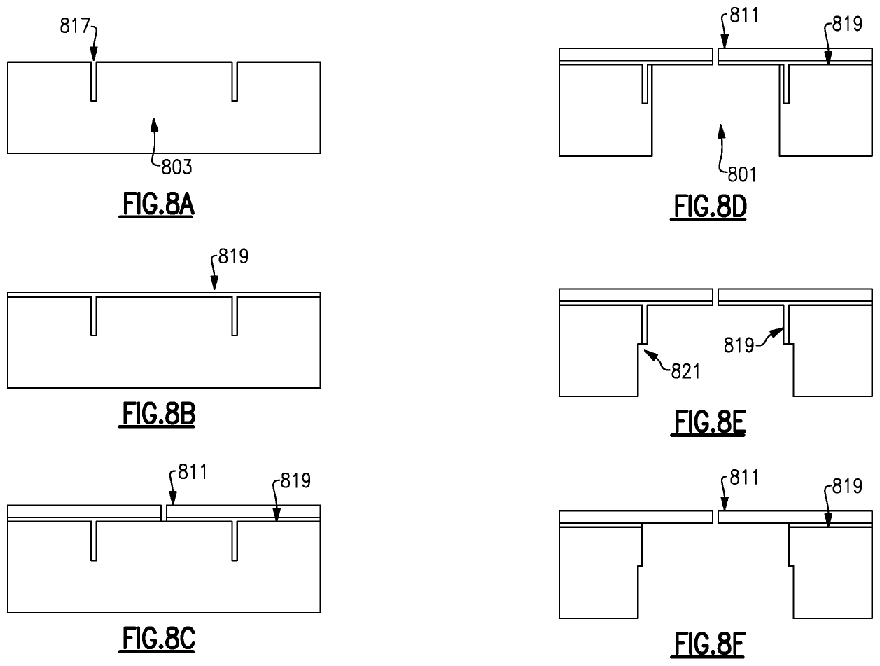

FIG. 8A-8F illustrate a cross-sectional view of a second method for making a piezoelectric MEMS microphone. It will be noted that the figures are for illustrative purposes only, and the features are not to scale. The cross-sectional view is taken along the line A shown in FIG. 5A, such that the trenches and cavities as described in the embodiments herein, may be created in any shape in the plane of the surface of the silicon. Preferably the shape of trenches on the surface of the substrate are such that the edge of the cavity walls are manufactured with indents to correspond to the protrusion in the one or more electrodes. Therefore, in the preferred embodiment, the trenches are shaped such that the edge of the cavity wall has two straight edges, and a semicircle or semi ellipse indent in the center of the two straight edges. As described in relation to the embodiment of FIG. 4, the electrode preferably has a protrusion with a 300 micrometer width and a depth of 5 micrometers. Therefore, the cavity wall is manufactured to have an indent of width 300 micrometers and a depth of 5 micrometers. The cavity wall and electrodes may be manufactured such that there is a small overlap, to take into account manufacturing tolerances, which may be around 2-3 micrometers.

As described in relation to FIG. 7, in the preferred embodiment the cavity comprises four walls comprising two end walls and two side walls, such that they meet at right angles to form a rectangular or square cross-section. The embodiment also comprises four cantilevered beams, such that that each beam has a fixed end supported by the anchor region of the device, i.e., supported by the cavity walls. Therefore, it is noted that the methods described herein, such as etching, will be applied to the additional two cavity walls and additional two beams. It will be noted that any shape of cavity may be used, such that the four walls do not meet at right angles, or such that there may only be three walls. It will be noted that any shape of beam may be used, such that the beams extend to form a rectangle in the plane parallel to the surface of the substrate, or such that there is only one beam. The substrate is substantially deep such that the cavity may formed having a depth of around 400 micrometers.

FIG. 8A shows the step of etching two trenches 817 into a substrate 803, from the front side. The substrate is preferably silicon, but it will be appreciated that it may be any suitable material. The trenches may be formed perpendicular to the surface of the substrate, such that they extend toward the back of the substrate at an angle substantially 90 degrees from the surface of the substrate. Although shown as a cross-sectional view, it will be noted that in a plan view, the trenches will extend in the plane of the surface of the substrate, such that they form trenches to result in an edge of the cavity wall with an indent to correspond to the protrusion of the one or more electrodes. The etching process used to form the trenches may be deep reactive-ion etching (DRIE), an anisotropic etch process, forming walls around 90 degrees to the surface of the substrate. It will be noted that the etching process may be any suitable anisotropic etching process. The trenches extend at least 0.6 micrometers into the substrate, however it will be appreciated that the trenches may be any depth, and may be chosen to allow for the deflection of the beam into the cavity.

FIG. 8B shows the step of oxidizing the top layer of the substrate 803 and oxidizing the sections of the substrate 803 that form the walls of the trenches. The trenches may be manufactured to be such a width that the oxidation process forms a sufficient layer of oxide that the trenches are filled with oxide. The oxidation process may include thermal oxidation. In the embodiment in which the substrate is formed from silicon, the oxidized layer will be composed of silicon dioxide. It is noted that the oxidized layer formed will be dependent on the material of the substrate. It will be appreciated that the layer of oxide may be any thickness sufficient to protect the necessary parts from etching in the steps described hereafter.

FIG. 8C shows the step of defining a piezoelectric beam. It will be noted that the cross-sectional view illustrates the beams as two-dimensional, however, the beams extend parallel to the surface of the substrate, such that it is three-dimensional, and may have a triangular or rectangular cross-section from a plan view. As noted above, the following method may be repeated to define the two end walls, and the other edges of the beam. As illustrated, at least one piezoelectric film layer 811 is formed on the front side of the silicon dioxide layer 819, such that the silicon dioxide 819 layer separates the substrate 803 and the piezoelectric film layer 811. The at least one piezoelectric film layer is formed by a physical vapor deposition. The beams are defined by anisotropic etching of the piezoelectric layer, or layers, and the layer of silicon dioxide 819 on the back side of the piezoelectric material, from the front side of the device. The etch is perpendicular to the surface of the piezoelectric film layer, and the etch is of a thickness such that the gap between the cantilevered beams is preferably 100 nanometers to 1 micrometer. However, it will be appreciated that the etch may be any thickness suitable for achieving the desired sensitivity. It will be noted that the etch is preferably in the center of the piezoelectric film layer, however it may be positioned to one side, or in line with a cavity wall. It will be noted that for illustrative purposes additional features in the embodiment, such as electrodes, are not included in the figures. However, it will be noted that these may be deposited layer by layer on and/or between the piezoelectric layers, during this step. The electrode is patterned after deposition. It will be noted that any suitable conductive material can be used for the electrodes, for example molybdenum or titanium, or others.

FIG. 8D shows the first step of forming the cavity 801. The cavity is etched from the back side of the device, using an anisotropic etch. This etching results in substantially perpendicular cavity walls. The etching may be performed such that the walls created follow the shape of the silicon dioxide trenches, i.e., the etching may form an indent, such that only a thin layer of silicon remains on the inside of the silicon dioxide trenches. The cavity is etched by silicon etching, such that the silicon dioxide layer between the beam and substrate is not etched. The cavity etched in this step may be narrower than the width between the two silicon dioxide trenches, so that there is excess silicon on the walls, as shown in FIG. 8D. This first step of etching the cavity defines the depth of the cavity, i.e., it is stopped at the silicon dioxide layer underneath the cavity.

FIG. 8E shows the second step of forming the cavity. In this step an isotropic etch is used to remove excess silicon at the walls of the cavity, but does not etch the silicon dioxide layers. It will be noted that any suitable isotropic etchant may be used. Preferably Sulfur hexafluoride (SF₆) is used to etch the silicon, as it does not etch silicon dioxide. An isotropic etch results in an etching in all directions, as opposed to the anisotropic etchant. As illustrated in FIG. 8E, the excess silicon located on the inside of the silicon dioxide filled trench 819 is etched away. The upper section of the cavity wall is consequently composed of silicon dioxide. It will be noted that due to the isotropic etching process, the section of the cavity wall not lined with silicon dioxide may be etched, such that a step 821 in the wall may be created.

FIG. 8F shows the final step of the etching process. In this step an isotropic etch is used to remove the silicon dioxide 819 from the cavity wall, and remove the silicon dioxide layer on the cavity side of the piezoelectric film layer. It will be noted that any suitable isotropic etchant may be used. The layer of silicon dioxide located between the piezoelectric film layer 811 and the substrate 803 is not etched away, due to its protection by the remaining silicon, which the silicon dioxide etching does not remove. This remaining layer acts as an insulating layer as described herein. After the removal of the silicon dioxide layer on the cavity side of the beam, the beam will bend about its fixed end according to the stress of the piezoelectric film layer.

It will be appreciated that the method as described in relation to FIGS. 8A-F result in an accurately defined cavity. The method results in edges of the cavity walls which are accurately aligned with the shape of the electrode, as the etching of the silicon trenches is performed from the front side of the cavity, which may be more accurate than etching an accurate wall from the back side of the substrate.

The above mentioned method may be used for the manufacture of any device, especially in an embodiment in which accuracy is preferable to the functioning of the device.

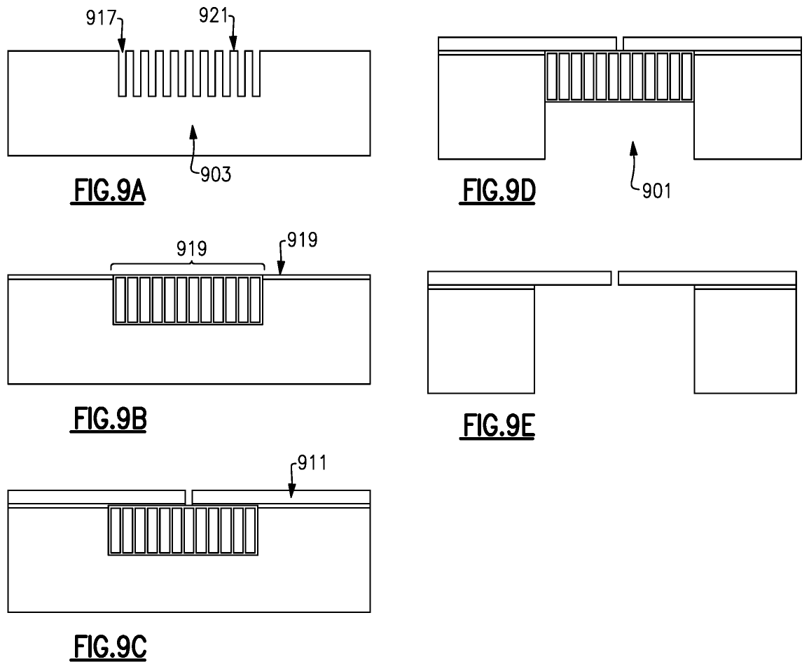

FIGS. 9A-9F show cross-sectional views of structures illustrating steps of a third, alternative, method of manufacturing a piezoelectric MEMS microphone. As noted in the embodiment illustrated in FIG. 8, although the beam and cavity are shown as two dimensional due to the cross-sectional view of the figure, the beam and cavity are three-dimensional. In FIGS. 9A-F, as in FIGS. 8A-F, the cavity may have any shape in the cross-section of the plan view, and the beams may also have any shape in the cross-section of the plan view. In the preferred embodiment, the beams are triangular in the cross-section of the plan view, and the cavity is shaped as described in any embodiment described herein.

FIG. 9A shows the step of etching multiple trenches 917 into the substrate 903 from the front side. The steps of forming the trenches described in the present embodiment may be the same as those as described in relation to FIG. 8A. The forming of the trenches creates silicon pillars 921. The trenches 917 and pillars 921 may be the same width, or they may be different widths. It will be noted that although illustrated with ten trenches, any number of trenches may be etched. As noted in relation to the embodiment illustrated in FIG. 8, the trenches extend parallel to the surface of the substrate, such that the pillars formed in this embodiment will be rectangular in cross-section. The length of each pillar in relation to the others may be chosen such that following their etching, as described herein, will form a cavity with the desired shape, i.e., a cavity wherein each wall has two straight edges, and an indent in the center of the two straight etches.

FIG. 9B shows the step of oxidizing the substrate, including oxidizing the silicon pillars formed in the method of FIG. 9A. The oxidizing of silicon may include thermal oxidation. The thickness of the pillars are chosen such that the thermal oxidation may consume the entirety of the silicon pillar. After the oxidization process, the trenches are filled with silicon dioxide due to silicon dioxide being grown on the surface of the silicon, and the silicon of the pillars have been oxidized to form pure silicon dioxide. As in FIG. 8B, the surface of the substrate has also been oxidized, such that a layer of silicon dioxide is coating the front side of the device.

FIG. 9C shows the defining of the beam. This process is the same as the process described in relation to FIG. 8C. The etch of the piezoelectric layer 911, or layers, and the layer of silicon dioxide 919 located between the layers and the substrate, is preferably in the center of the piezoelectric film layer.

The step illustrated in FIG. 9D is the same as described in relation to FIG. 8D.

FIG. 9E shows the removal of the silicon dioxide from the backside of the device. The method for removing the silicon dioxide is the same as described in the embodiment of FIG. 8E. This etching removes the silicon dioxide on the backside of the beam, and the silicon dioxide formed from the trenches and pillars.

The method of FIGS. 9A-9E as described above provides a step of requiring a smaller volume of silicon to be etched than other methods, also giving an extra degree of freedom to the etching. Although, more silicon dioxide is required to be removed by the isotropic silicon dioxide etch in the method of FIGS. 9A-9E, silicon dioxide etching is a fast process.

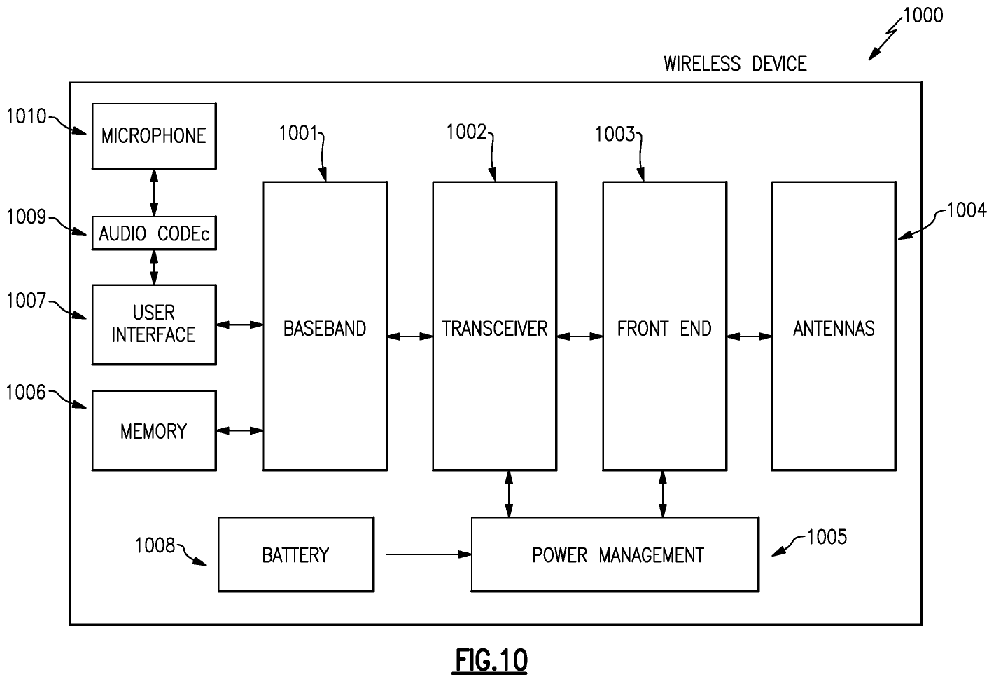

FIG. 10 is a schematic diagram of one embodiment of a wireless device 1000. The wireless device can be, for example but not limited to, a portable telecommunication device such as, a mobile cellular-type telephone. The wireless device includes a microphone arrangement 1100, including an improved microphone as described herein in relation to FIGS. 4 to 10, and may include one or more of a baseband system 1101, a transceiver 1102, a front end system 1103, one or more antennas 1104, a power management system 1105, a memory 1106, a user interface 1107, a battery 1108, and audio codec 1109. The microphone arrangement may supply signals to the audio codec 109 which may encode analog audio as digital signals or decode digital signals to analog. The audio codec 1109 may transmit the signals to a user interface 1107. The user interface 1107 transmits signals to the baseband system 1101. The transceiver 1002 generates RF signals for transmission and processes incoming RF signals received from the antennas.

The transceiver 1003 aids in conditioning signals transmitted to and/or received from the antennas 1004.

The antennas 1004 can include antennas used for a wide variety of types of communications. For example, the antennas 1004 can include antennas 1004 for transmitting and/or receiving signals associated with a wide variety of frequencies and communications standards.

The baseband system 1001 is coupled to the user interface to facilitate processing of various user input and output, such as voice and data. The baseband system 1001 provides the transceiver 1002 with digital representations of transmit signals, which the transceiver 1002 processes to generate RF signals for transmission. The baseband system 1001 also processes digital representations of received signals provided by the transceiver 1002. As shown in FIG. 10, the baseband system 1001 is coupled to the memory to facilitate operation of the wireless device.

The memory can be used for a wide variety of purposes, such as storing data and/or instructions to facilitate the operation of the wireless device and/or to provide storage of user information.

The power management system 1005 provides a number of power management functions of the wireless device.

The power management system 1005 receives a battery voltage from the battery 1008. The battery 1008 can be any suitable battery for use in the wireless device, including, for example, a lithium-ion battery.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A piezoelectric microelectromechanical systems microphone, comprising:
a substrate including walls defining a cavity and at least one of the walls defining an anchor region;
a piezoelectric film layer supported by the substrate at the anchor region; and
an electrode disposed over the piezoelectric film layer and adjacent the anchor region and including an edge adjacent the anchor region having two straight portions and a protruding portion between the two straight portions, and the wall of the cavity that defines the anchor region including an indent corresponding in shape to the protruding portion of the electrode.

2. The microphone of claim 1 wherein the protruding portion of the electrode defines a curve.

3. The microphone of claim 1 wherein the protruding portion of the electrode defines a polygon.

4. The microphone of claim 1 wherein the protruding portion is in the middle of the edge of the electrode.

5. The microphone of claim 1 wherein the piezoelectric film layer and electrode define a beam, wherein the beam is cantilevered such that it has a free end and a fixed end.

6. The microphone of claim 5 wherein the beam further comprises a second piezoelectric layer.

7. The microphone of claim 1 wherein the piezoelectric film layer has a triangular shape.

8. The microphone of claim 7 wherein the electrode is a truncated triangle with a protruding portion, such that the free end of the piezoelectric film layer is exposed.

9. The microphone of claim 1 wherein the protruding portion of the electrode has a width of 300 micrometers and a depth of 5 micrometers.

10. The microphone of claim 1 further comprising at least one additional electrode.

11. A method of making a piezoelectric microelectromechanical systems microphone, the method comprising:
depositing one or more electrodes each including an edge adjacent an anchor region having two straight portions and a protruding portion between the two straight portions; and
etching a cavity including one or more walls each having an indent corresponding in shape to the protruding portion of the electrode.

12. The method of claim 11 wherein the etching of the cavity further comprises:
etching a trench in a silicon substrate from a front side;
filling the trench with a silicon dioxide and oxidizing a surface of a substrate to form an oxidation layer;
applying a piezoelectric film layer over the oxidation layer;
etching a gap in the piezoelectric film layer from the front side;
etching the silicon substrate from the back side; and
etching the silicon dioxide from the back side.

13. The method of claim 12 further comprising etching a second trench wherein the first and second trenches define the edges of the cavity.

14. The method of claim 13 wherein the trenches each comprise two straight edges and an indent to correspond to the protrusion of the electrode

15. The method of claim 14 wherein the indent has a width of 300 micrometers and a depth of 5 micrometers.

16. The method of claim 12 further comprising etching two or more additional trenches, defining pillars.

17. The method of claim 16 further comprising oxidizing the pillars.

18. The method of claim 17 wherein the etching of the silicon dioxide comprises etching the pillars, to form a cavity.

19. A wireless mobile device comprising:
one or more antennas;
a front end system that communicates with the one or more antennas; and
one or more piezoelectric microelectromechanical systems microphones, each microphone including:
a substrate having walls defining a cavity at least one of the walls defining an anchor region;
a piezoelectric film layer supported by the substrate at the anchor region;
an electrode disposed over the piezoelectric film layer and adjacent the anchor region and having an edge adjacent the anchor region including two straight portions and a protruding portion between the two straight portions, and the wall of the cavity that defines the anchor region having an indent corresponding in shape to the protruding portion of the electrode.

20. The wireless mobile device of claim 19 wherein the protruding portion of the electrode defines a curve.
